(19) United States
(12) Patent Application Publication
(10) Pub. No.: US 2020/0020617 A1
(43) Pub. Date: Jan. 16, 2020

(54) RESIN ENCAPSULATING MOLD AND MANUFACTURING METHOD FOR SEMICONDUCTOR DEVICE

(71) Applicant: ABLIC Inc., Chiba-shi (JP)

(72) Inventors: Yuta KIMURA, Chiba-shi (JP); Kiyoaki KADOI, Chiba-shi (JP); Yasuhiro TAGUCHI, Chiba-shi (JP)

(21) Appl. No.: 16/506,310

(22) Filed: Jul. 9, 2019

(30) Foreign Application Priority Data
Jul. 12, 2018 (JP) 2018-131928

(51) Int. Cl. H01L 23/495; H01L 23/29; H01L 23/31; H01L 21/56

(52) U.S. Cl. CPC H01L 23/49544; H01L 23/49551; H01L 23/49575; H01L 21/565; H01L 23/293; H01L 23/315; H01L 23/49517

(57) ABSTRACT

Provided is a resin encapsulating mold by which deformation of tie bars of a lead frame is prevented during resin encapsulation. The resin encapsulating mold having a cavity by which a lead frame assembly having a semiconductor element is held and encapsulated with a resin to form a semiconductor device, includes protrusions (23) outside tie bar clamping portions (24a and 24b) formed around a cavity (22), to thereby prevent deformation of tie bars (2).

### RELATED APPLICATIONS

Priority is claimed on Japanese Patent Application No. 2018-131928, filed on Jul. 12, 2018, the content of which is incorporated herein by reference.

### BACKGROUND OF THE INVENTION

### 1. Field of the Invention

The present invention relates to a resin encapsulating mold and a method of manufacturing a semiconductor device.

### 2. Description of the Related Art

FIG. 5A and FIG. 5B are views for illustrating a conventional resin encapsulating mold and a lead frame in prior art. FIG. 5A is a plan view, and FIG. 5B is a cross-sectional view taken along the line A-A of FIG. 5A. The resin encapsulating mold includes a lower mold 31a in which a cavity 32 for molding a resin encapsulating body is formed, and an upper mold (not shown) in which a lead frame 1 is sandwiched with the lower mold 31a and a cavity 32 similar to that of the lower mold 31a is formed.

In encapsulation with a resin, the lead frame 1 having the semiconductor element mounted thereon is first placed on the lower mold 31a. Next, the lead frame 1 is sandwiched with the upper mold, a molten resin is injected into the cavity 32 and cured, and then a molded resin encapsulating body is removed from the mold to complete the molding. During the resin encapsulation, the resin which has been injected into the cavity 32 flows in through a gap between the lead frame 1 and an inner surface of the mold. Since the flow of the molten resin is blocked by tie bars 2 of the lead frame 1, a considerable resin pressure is applied on the tie bars 2, requiring the tie bars 2 which withstand the resin pressure (see Japanese Patent Application Laid-open No. H2-165644, for example).

However, in semiconductor devices in recent years, the number of terminals is increased to reduce a pitch between leads, and it is difficult to cut the tie bar connecting the leads. A cutting punch is used to cut the tie bars, and when the pitch between the leads becomes a thickness of the lead frame or less, an excessive load is applied on the cutting punch. Though the cutting can be facilitated by thinning of the tie bars, the thin tie bars 2 may be deformed by the pressure during the resin encapsulation in some cases, with the result that the molten resin cannot be prevented from flowing out.

### SUMMARY OF THE INVENTION

In the present invention a resin encapsulating mold is provided with which tie bars are not deformed by a pressure during resin encapsulation even when tie bars are thin.

According to at least one aspect of the present invention there is provided a resin encapsulating mold having a cavity by which a lead frame assembly having a semiconductor element and a plurality of leads connected to each other by tie bars is held and encapsulated with a resin to form a semiconductor device, the resin encapsulating mold including protrusions outside tie bar clamping portions formed around the cavity.

According to at least another aspect of the present invention there is provided a method of manufacturing a semiconductor device by which a lead frame assembly having a semiconductor element is encapsulated with a resin to form a semiconductor device, the method including: preparing the lead frame assembly in which a plurality of leads are connected to each other by tie bars, and in which the semiconductor element electrically connected to the plurality of leads is mounted on a die pad: preparing a resin encapsulating mold including protrusions outside tie bar clamping portions: placing the lead frame assembly on the resin encapsulating mold so that outer side surfaces of the tie bars and inner side surfaces of the protrusions are close to each other; sandwiching the lead frame assembly between an upper mold and a lower mold of the resin encapsulating mold; encapsulating the lead frame assembly with the resin to form a resin encapsulating body; cutting the tie bars from the resin encapsulating body; and forming the plurality of leads exposed from the resin encapsulating body.

As described above, with the resin encapsulating mold according to the present invention, the deformation of the tie bars hardly occurs during the resin encapsulation and bending of the leads accompanying the deformation is suppressed.

### BRIEF DESCRIPTION OF THE DRAWINGS

FIG. 1A and FIG. 1B are views for illustrating a resin encapsulating mold and a lead frame according to the first embodiment of the present invention.

FIG. 2A. FIG. 2B, and FIG. 2C are enlarged views for illustrating the resin encapsulating mold and the lead frame according to the first embodiment of the present invention.

FIG. 3A, FIG. 3B, FIG. 3C, FIG. 3D, and FIG. 3E are views for illustrating a manufacturing process of a semiconductor device with the use of the resin encapsulating mold according to the first embodiment of the present invention.

FIG. 4A and FIG. 4B are views for individually illustrating the resin encapsulating mold and the lead frame according to the first embodiment of the present invention.

FIG. 5A and FIG. 5B are views for illustrating a conventional resin encapsulating mold and a lead frame.

### DETAILED DESCRIPTION OF THE PREFERRED EMBODIMENTS

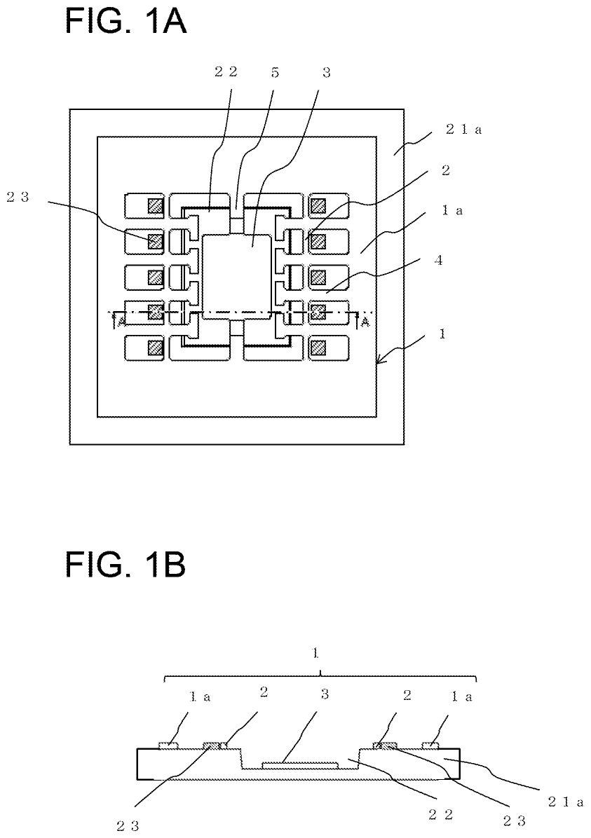

Now, embodiments of the present invention are described with reference to the drawings. FIG. 1A and FIG. 1B are views for illustrating a resin encapsulating mold and a lead frame according to the first embodiment of the present invention. FIG. 1A and FIG. 1B show an instant at which a lead frame 1 is placed on a lower mold 21a of the resin encapsulating mold. FIG. 1A is a plan view, and FIG. 1B is a cross-sectional view taken along the line A-A of FIG. 1A.

As illustrated in FIG. 1A, the lead frame 1 includes a die pad 3 on which the semiconductor element is placed, suspension leads 5 configured to connect the die pad 3 to a frame portion 1a, leads 4 provided at intervals around the die pad 3, and tie bars 2 each connecting a lead 4 with an adjacent lead. As illustrated in FIG. 1B, the die pad 3 is set down with respect to the leads 4 and brought into contact with a bottom surface of a cavity 22 of the lower mold 21a. Protrusions 23 are formed outside a peripheral edge portion of the cavity 22, and the tie bars 2 are arranged close to inner side surfaces in the direction of the cavity 22 as seen from the protrusions 23. The protrusions 23 are all formed to have a height that is smaller than a thickness of the lead frame 1. When the lead frame 1 has a size exceeding 10 cm per side, a variation in thickness in a plane thereof is large, and the height of the protrusions 23 is set to be lower than the minimum value of the thickness. In view of the function of the protrusions 23, the height is set to have half the thickness of the leads 4 or more. In a case where the lead frame 1 is clamped by an upper mold 21b and the lower mold 21a, even when the thickness of the leads 4 becomes somewhat thinner and the height thereof is reduced, upper surfaces of the protrusions 23 are thereby not brought into contact with a lower surface of the upper mold that opposes the protrusions 23, and sufficient clamping can be performed.

In FIG. 1A, four leads 4 are arranged on each side around the die pad 3, a total of five tie bars 2 including three tie bars 2 connecting a lead 4 with an adjacent lead, and two tie bars 2 connecting a lead 4 with the frame portion 1a are arranged on each side of the die pad 3. Each of the protrusions 23 is assigned to each of the tie bars 2 so that a total of five protrusions 23 are arranged on each side of the cavity 22.

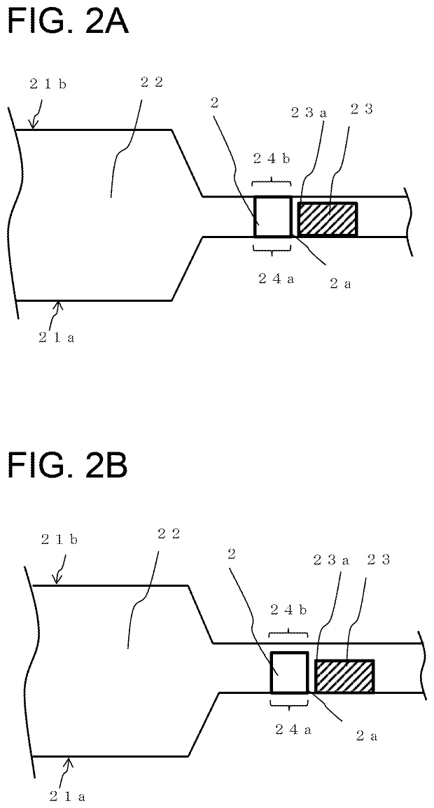

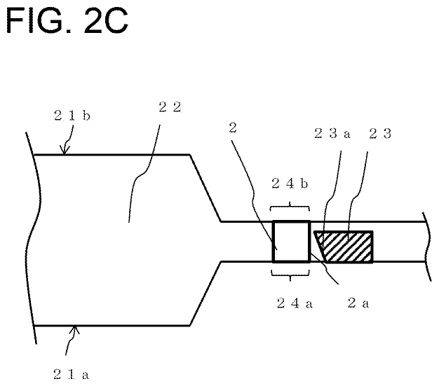

FIG. 2A to FIG. 2C are enlarged views of the resin encapsulating mold and the lead frame 1 according to the first embodiment of the present invention and are partially enlarged views of a region in which the tie bar 2 and the protrusion 23 are close to each other. FIG. 2A shows a cross section of an area in which the upper mold 21b of the resin encapsulating mold and the lead frame 1 are brought into contact with each other, and FIG. 2B shows a cross section of an area in which the upper mold 21b of the resin encapsulating mold and the lead frame 1 are not brought into contact with each other.

As illustrated in FIG. 2A, an outer side surface 2a of the tie bar 2 and an inner side surface 23a of the protrusion 23 are arranged close to each other, and the outer side surface 2a and the inner side surface 23a are formed to be perpendicular to the upper surface of the lower mold 21a. Specifically, the outer side surface 2a of the tie bar 2 and the inner side surface 23a of the protrusion 23 are arranged to have a distance from 20 μm to 50 μm. A bottom surface of the tie bar 2 is in contact with a tie bar clamping portion 24a of the lower mold 21a, and the upper surface of the tie bar 2 is in contact with a tie bar clamping portion 24b of the upper mold 21b. Then, as described above, the height of the protrusion 23 is set to be smaller than the thickness of the lead 4. The lead frame 1 has a variation in thickness, and the variation in thickness also exists in the region of the tie bar 2. When the tie bar 2 is clamped by the upper mold 21b and the lower mold 21a, the tie bar 2 in a thick area is sufficiently crushed, and the tie bar 2 in a thin area is crushed little.

In this manner, the tie bar in the area in which the tie bar is crushed little is not sufficiently clamped by the upper mold 21b and the lower mold 21a, and the tie bar 2 may be bent by a resin pressure in some cases. However, in the case where the outer side surface 2a of the tie bar 2 is perpendicular to the lower mold 21a as described above, giving a perpendicular shape to the inner side surface 23a of the protrusion 23 can prevent the tie bar 2 from bending. More preferably, the inner side surface 23a of the protrusion 23 is inclined to the tie bar 2 side to have an inversely tapered shape as illustrated in FIG. 2C.

FIG. 2B is a cross-sectional view of the protrusion in an area in which the upper mold 21b of the resin encapsulating mold and the lead frame 1 are not in contact with each other. The outer side surface 2a of the tie bar 2 and the inner side surface 23a of the protrusion 23 are arranged close, and the outer side surface 2a and the inner side surface 23a are formed to be perpendicular to an upper surface of the lower mold 21a. Specifically, the outer side surface 2a of the tie bar 2 and the inner side surface 23a of the protrusion 23 are arranged to have a distance from 20 μm to 50 μm. The bottom surface of the tie bar 2 is in contact with the tie bar clamping portion 24a of the lower mold 21a, and the upper surface of the tie bar 2 is not in contact with the tie bar clamping portion 24b of the upper mold 21b, with the result that there is a gap between the upper surface of the tie bar 2 and the tie bar clamping portion 24b of the upper mold 21b.

In order to facilitate filling of the resin in the resin encapsulating mold, an area as a relief vent is partially provided without clamping all the surfaces of the lead frame 1, and the relief vent is a gap for discharging only air in the mold to the outside and has a size from about 5 μm to about 10 μm. With this setting, although air is discharged to the outside of the system, a molten resin in the mold can be prevented from flowing out of the mold.

In the area in which the upper surface of the tie bar 2 is not in contact with the tie bar clamping portion 24b of the upper mold 21b as described above, the clamping by the tie bar clamping portion 24b of the upper mold 21b and the tie bar clamping portion 24a of the lower mold 21a is not performed. Consequently, deformation in which the tie bar 2 bends to the right (in the direction of the outer side surface 2a of the tie bar) tends to occur by the resin pressure applied from the left in FIG. 2B, with the result that, even when the thickness of the lead frame 1 is about 0.4 mm, the tie bar 2 may be unable to withstand the resin pressure, resulting in bending deformation. In the case where the outer side surface 2a of the tie bar 2 is perpendicular to the lower mold 21a, the tie bar 2 can be prevented from bending by forming the inner side surface 23a of the protrusion 23 to have a perpendicular shape. Further, while the outer side surface 2a of the tie bar 2 being perpendicular, the inner side surface 23a of the protrusion 23 may be inclined to the tie bar 2 side so that the inner side surface 23a has the inversely tapered shape, to thereby prevent the tie bar 2 from bending more effectively.

As described above, with the formation of the protrusions 23, since the outside of the cavity 22 which is surrounded by the tie bar 2 and the leads 4, and which is formed when the lead frame 1 is sandwiched between the upper mold 21b and the lower mold 21a is blocked by the protrusions 23, the pressure generated by the molten resin injected into the cavity 22 is blocked by the protrusions 23 via the tie bars 2, and hence the tie bars 2 of the lead frame 1 do not deform. The deformation of the leads 4 accompanying the deformation of the tie bars 2 can thus be prevented.

Even when a pitch between the leads is reduced, and a width of a cutting punch becomes the thickness of the lead frame or less, thin tie bars can be adapted, with the result that the following effect is obtained: an excessive load is less liable to be applied on the cutting punch to facilitate cutting and increase the life of the cutting punch.

Moreover, with the formation of the protrusions 23, the lead frame 1 can be easily positioned, and hence a gate pin that is required in the related art becomes unnecessary in the embodiment of the present invention.

The embodiment in which the protrusions 23 are formed on the lower mold 21a has been described above, but the protrusions 23 may be formed on the upper mold 21b. Alternatively, the protrusions 23 may be formed on both the upper mold 21b and the lower mold 21a.

Next, a manufacturing process of a semiconductor device is described with reference to the drawings.

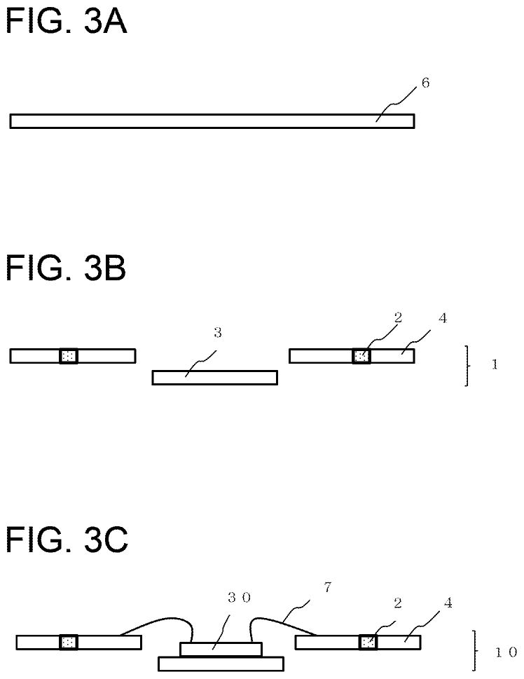

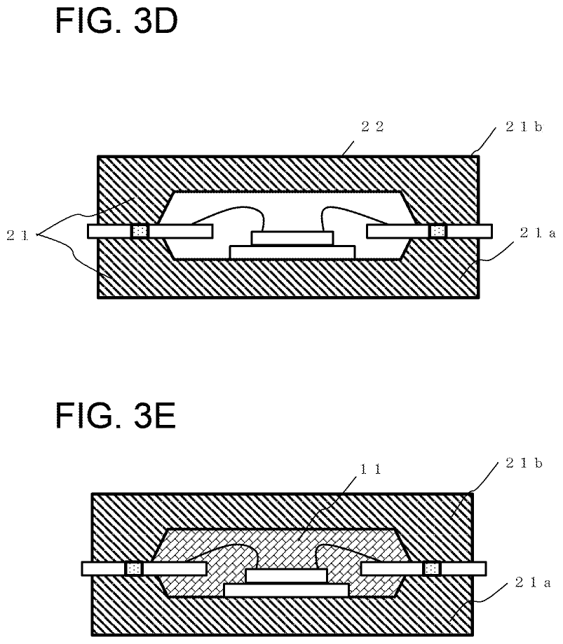

FIG. 3A to FIG. 3E are views for illustrating the manufacturing process of the semiconductor device with the use of the resin encapsulating mold according to the first embodiment of the present invention.

First, as illustrated in FIG. 3A, as a material of the lead frame, a thin plate 6 made of a Cu alloy having a thickness of about 0.20 mm which has a relatively high heat conduction and a high strength is prepared. Next, as illustrated in FIG. 3B, the die pad 3, the leads 4, the suspension leads 5 (not shown), and the tie bars 2 are integrally formed by punching. For the formation of the lead frame, etching may be used instead of punching. Then, at least surfaces of regions of the leads 4 to which metal wires 7 are connected are plated with Ag. Next, the suspension leads 5 are bent to set down the die pad 3. An amount of setting down at this time is adjusted to a degree at which a rear surface of the die pad 3 is exposed from a bottom surface of the semiconductor device that is encapsulated with a resin. Through the preparation of the thin plate, the punching, and other processing described above, the lead frame 1 used in the semiconductor device is completed.

Next, as illustrated in FIG. 3C, a semiconductor element 30 is mounted and fixed on the die pad 3 via an adhesive, and further, a bonding pad on the semiconductor element 30 fixed on the die pad 3 and the leads 4 are electrically connected with the use of the metal wire 7 made of Au (gold) or the like to form a lead frame assembly 10.

Next, as illustrated in FIG. 3D, the lead frame assembly 10 having the semiconductor element 30 fixed thereon is placed on the lower mold 21a of a resin encapsulating mold 21. Although not shown, the tie bars 2 are simultaneously arranged between the cavity 22 of the lower mold 21a and the protrusions 23. At this time, the outer side surfaces of the tie bars are arranged near the inner side surfaces of the protrusions.

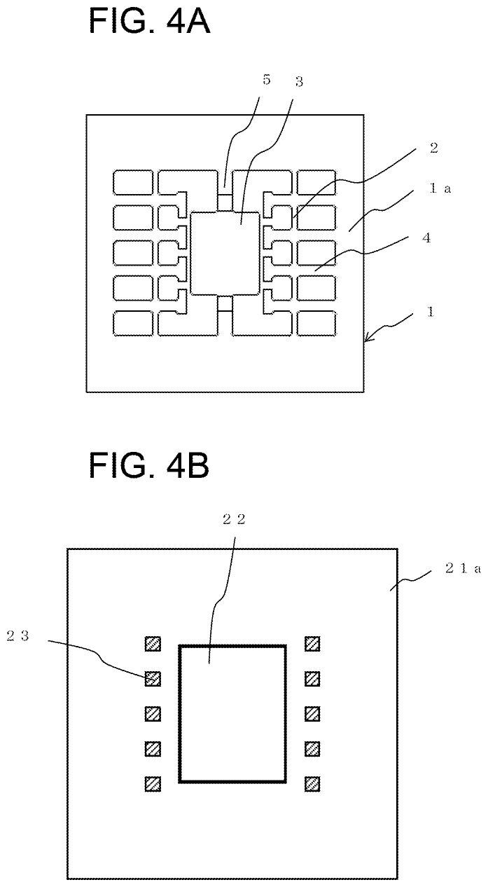

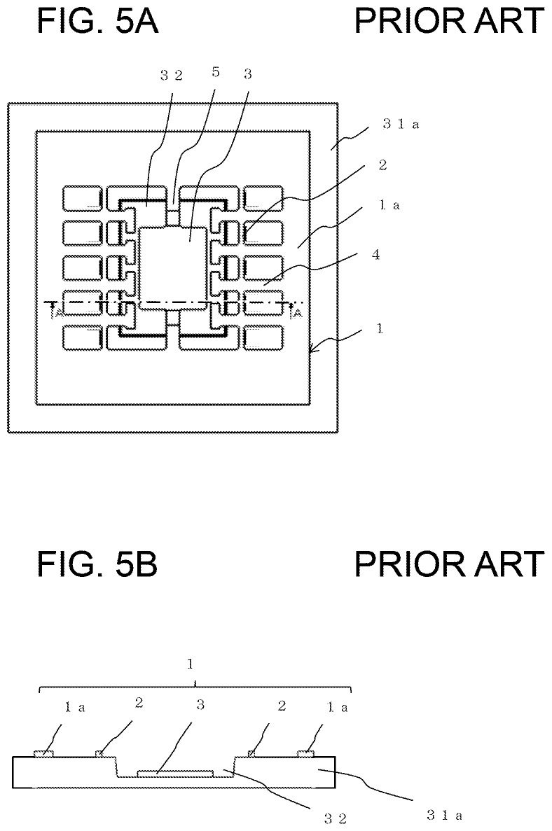

In FIG. 4A and FIG. 4B, the lead frame before the placing and the lower mold of the resin encapsulating mold are illustrated separately. FIG. 4A is a plan view of the lead frame 1 which has a shape having the die pad 3, the leads 4, the suspension leads 5, and the tie bars 2. FIG. 4B is a plan view of the lower mold 21a of the resin encapsulating mold which has a shape having the protrusions 23 around the cavity 22 at the center and outside the peripheral edge portion of the cavity 22. The same number of protrusions 23 as the number of tie bars 2 are formed, and in this example, five protrusions 23 are formed on each side, with the result that ten protrusions 23 are formed on both sides. A plan view in which the lead frame 1 is placed on the lower mold 21a is FIG. 1A described above.

Next, as illustrated in FIG. 3E, the lead frame 1 is sandwiched between the upper mold 21b and the lower mold 21a of the resin encapsulating mold 21 which is heated to about 180° C. to clamp base portions of the leads 4 and the tie bars 2 from above and below, and a flow of a molten encapsulating resin is made to fill the cavity 22. Although not shown, at this time, the protrusions 23 are arranged near the outside of the tie bars 2, and hence the tie bars 2 do not have bending deformation even when the tie bars 2 are thin. Moreover, the bending of the leads accompanying with the deformation does not occur.

Thereafter, after the encapsulating resin is heat-cured, a resin encapsulating body 11 of the semiconductor device is removed from the resin encapsulating mold 21, and then the leads 4 are covered by tin plating, for example. Thereafter, the tie bars 2 and burrs of the resin filled between the leads 4 inside the tie bars 2 are cut with the use of a cutting device to separate adjacent leads 4 from each other. When the tie bars 2 are formed near the resin encapsulating body 11, it is only required to cut the tie bars 2. Next, distal ends of the leads 4 exposed from the resin encapsulating body 11 are cut from the frame portion and formed into a predetermined shape by a lead forming apparatus. Through the above-mentioned process, the semiconductor device is completed.

The embodiment in which the protrusions 23 are formed on the lower mold 21a has been described above, but the protrusions 23 may be formed on the upper mold 21b. Alternatively, the protrusions 23 may be formed on both the upper mold 21b and the lower mold 21a.

What is claimed is:

1. A resin encapsulating mold having a cavity by which a lead frame assembly having a semiconductor element and a plurality of leads connected to each other by tie bars is held and encapsulated with a resin to form a semiconductor device,
the resin encapsulating mold, comprising:
protrusions outside tie bar clamping portions formed around the cavity.

2. The resin encapsulating mold according to claim 1, wherein the protrusions have a height that is smaller than a thickness of the tie bars of the lead frame assembly.

3. The resin encapsulating mold according to claim 1, wherein the protrusions are formed on at least one of a lower mold and an upper mold of the resin encapsulating mold.

4. The resin encapsulating mold according to claim 2, wherein the protrusions are formed on at least one of a lower mold and an upper mold of the resin encapsulating mold.

5. The resin encapsulating mold according to claim 1, wherein an inner side surface of each of the protrusions which faces the cavity is inclined in an inversely tapered shape.

6. The resin encapsulating mold according to claim 2, wherein an inner side surface of each of the protrusions which faces the cavity is inclined in an inversely tapered shape.

7. The resin encapsulating mold according to claim 3, wherein an inner side surface of each of the protrusions which faces the cavity is inclined in an inversely tapered shape.

8. The resin encapsulating mold according to claim 4, wherein an inner side surface of each of the protrusions which faces the cavity is inclined in an inversely tapered shape.

9. A method of manufacturing a semiconductor device by which a lead frame assembly having a semiconductor element is encapsulated with a resin to form a semiconductor device, the method, comprising:
preparing the lead frame assembly in which a plurality of leads are connected to each other by tie bars, and in which the semiconductor element electrically connected to the plurality of leads is mounted on a die pad;
preparing a resin encapsulating mold including protrusions outside tie bar clamping portions;
placing the lead frame assembly on the resin encapsulating mold so that outer side surfaces of the tie bars and inner side surfaces of the protrusions are close to each other;
sandwiching the lead frame assembly between an upper mold and a lower mold of the resin encapsulating mold;
encapsulating the lead frame assembly with the resin to form a resin encapsulating body;
cutting the tie bars from the resin encapsulating body; and
forming the plurality of leads exposed from the resin encapsulating body.

10. The method of manufacturing a semiconductor device according to claim 9, wherein, in the preparing of the resin encapsulating mold, the protrusions are formed on at least one of the lower mold and the upper mold of the resin encapsulating mold.

11. The method of manufacturing a semiconductor device according to claim 9, wherein, in the sandwiching of the lead frame assembly, surfaces of the protrusions are not brought into contact with a surface of the resin encapsulating mold that is opposed to the protrusions.

12. The method of manufacturing a semiconductor device according to claim 10, wherein, in the sandwiching of the lead frame assembly, surfaces of the protrusions are not brought into contact with a surface of the resin encapsulating mold that is opposed to the protrusions.

13. The method of manufacturing a semiconductor device according to claim 9, wherein the cutting of the tie bars further comprises removing burrs of the resin filled between the tie bars and the resin encapsulating body.

14. The method of manufacturing a semiconductor device according to claim 10, wherein the cutting of the tie bars further comprises removing burrs of the resin filled between the tie bars and the resin encapsulating body.

15. The method of manufacturing a semiconductor device according to claim 11, wherein the cutting of the tie bars further comprises removing burrs of the resin filled between the tie bars and the resin encapsulating body.

16. The method of manufacturing a semiconductor device according to claim 12, wherein the cutting of the tie bars further comprises removing burrs of the resin filled between the tie bars and the resin encapsulating body.
